(19) United States
(12) Patent Application Publication
(10) Pub. No.: US 2013/0104982 A1
(43) Pub. Date: May 2, 2013

(54) ULTRASONICALLY-WELDED JUNCTION BOX

(71) Applicant: FIRST SOLAR, INC., Perrysburg, OH (US)

(72) Inventors: Pedro Gonzalez, Fremont, CA (US); Markus Beck, Scotts Valley, CA (US)

(73) Assignee: FIRST SOLAR, INC., Perrysburg, OH (US)

(21) Appl. No.: 13/664,920

(22) Filed: Oct. 31, 2012

Related U.S. Application Data
(60) Provisional application No. 61/552,057, filed on Oct. 27, 2011.
(60) Provisional application No. 61/552,148, filed on Oct. 27, 2011.

(51) Int. Cl. H01L 31/02; H01L 31/18

(52) U.S. Cl. CPC H01L 31/02008; H01L 31/18
USPC 136/259; 29/428; 228/110.1

(57) ABSTRACT

Methods and devices are described for allowing the ultrasonic welding of a junction box, having at least one overmolded element, to a cover panel of a photovoltaic module.

### CROSS-REFERENCE TO RELATED APPLICATION

This application claims priority to U.S. Provisional Application No. 61/552,057 which is hereby fully incorporated by reference. The present application is also related to Provisional Application No. 61/552,148, which is also hereby fully incorporated by reference.

### TECHNICAL FIELD

The present invention relates generally to photovoltaic modules and in particular to methods and devices for providing a junction box for a photovoltaic module.

### BACKGROUND

Photovoltaic modules are commonly installed outdoors to allow for direct sunlight exposure. Outdoor installation exposes the modules to moisture in the form of precipitation and humidity. Moisture can be harmful if it accesses the interior surfaces of the module as it can promote corrosion of surfaces within the module. Moisture can also promote structural damage if allowed to freeze within the module.

Junction boxes are typically attached over an opening in the back cover panel of a module using an adhesive, for example, a liquid or tape-based adhesive which can also serve as a sealant. The module opening typically allows at least two conductive tapes, which connect with the internal module conductors to be folded back at the edges of the opening for connection with external conductors which pass into a cavity defined by the junction box. While both sealants provide certain advantages, both are also associated with certain disadvantages. For instance, a liquid sealant may require substantial curing time, and therefore, can reduce manufacturing efficiency. Liquid sealants may also require pressure to be applied to the junction box while the sealant cures. Foam tape can provide instant tacking. Unfortunately, the bonding strength of foam tape decreases during exposure to high temperatures and high humidity.

Commercial and regulatory standards may require more rigorous testing of the bond strengths of a junction box including applying a load to a junction box while the module is exposed to high temperatures and high humidity. To ensure conformance, a solution is needed for affixing a junction box to the back panel of a module which provides instant tacking and ample bonding strength when exposed to high temperatures and high humidity.

### DESCRIPTION OF DRAWINGS

FIGS. 1A-1B depict graphical representations of a junction box according to one embodiment;

FIGS. 2A-2B depict graphical representations of a junction box according to another embodiment;

FIGS. 3A-3B depict graphical representations of a photovoltaic module including a junction box;

FIGS. 4A-4B depict a graphical representation of a junction box according to another embodiment;

FIG. 4C depicts a graphical representation of a junction box according to another embodiment;

FIG. 4D depicts a graphical representation of a junction box according to another embodiment;

FIGS. 5A-5D depict a graphical representation of a metal element which can buckle under applied pressure according to another embodiment;

FIG. 6 depicts a method for coupling a junction box to a back cover panel; and

FIG. 7 depicts a method for forming a junction box.

### DETAILED DESCRIPTION

Embodiments described herein are directed to a photovoltaic module including a front cover panel, back cover panel, photovoltaic cells between the front and back cover panels, and a junction box, also called a cord plate, provided over an opening in the back cover panel. The junction box may be ultrasonically-welded to the back cover panel, which may be made of a glass, and provides a cavity in which external conductors can be electrically connected to internal module conductors. Ultrasonic welding can include any industrial technique where high-frequency ultrasonic acoustic vibrations are applied to create a weld between similar or dissimilar materials. The junction box may include one or more metal elements which may securely couple the junction box to the back cover panel of the photovoltaic module by ultrasonic welding. One distinct advantage of coupling the junction box to the back cover panel by ultrasonic welding is that the junction box is instantly tacked to the back cover panel. As will be described in greater detail below, ultrasonic welding allows for rapid assembly of a photovoltaic module, even when liquid sealants are used, as ultrasonic welds can hold the junction box firmly in place while the liquid sealant is permitted to cure. According to another embodiment, the metal element(s) of a junction box may allow for buckling under a certain ultrasonic tool load for providing the necessary pressure for a sealing material to cure after the junction box is welded in place.

Other embodiments are directed to methods for coupling a junction box to a back cover panel of a photovoltaic module. The methods may include positioning a junction box relative to an opening in a back cover panel and ultrasonically welding one or more metal elements of the junction box to the back cover panel. In one embodiment, the back cover panel may be a glass cover panel. In other embodiments, the back cover panel may be a polymeric material including polymer foils or sheets which can be ultrasonically welded.

Other embodiments are directed to a junction box and method of forming the junction box. A junction box may be formed by positioning at least one metal element and overmolding a housing of the junction box to the at least one metal element. The at least one metal element of the junction box may be configured to be ultrasonically welded to the back cover panel of a photovoltaic module. According to another embodiment, at least one polymeric element of the junction box may be configured to be ultrasonically welded to the back cover panel, including a polymeric back cover panel, of a photovoltaic module

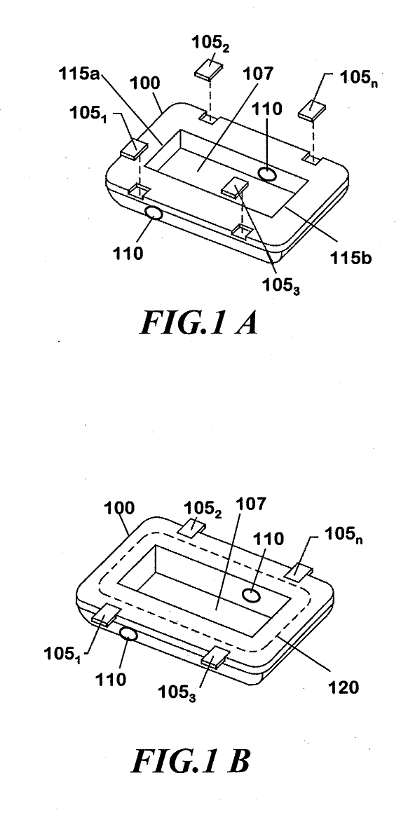

Referring now to the figures, FIGS. 1A-1B depict graphical representations of a bottom side of junction box 100 according to one embodiment. Referring first to FIG. 1A, a bottom disassembled view is depicted which includes a plurality of metal elements depicted as 105₁₋ₙ). The housing of junction box 100 is formed of a plastic or other moldable material overmolded onto metal elements 105₁₋ₙ. The metal elements 105₁₋ₙ are thus fixed to and integrated with junction box 100 and arranged to extend outwardly from junction box 100. Metal elements 105₁₋ₙ allow junction box 100 to be ultrasonically-welded to a back cover panel of a photovoltaic module. Metal elements 105₁₋ₙ may be any one of aluminum, copper, nickel, or any other suitable metal, which can be ultrasonically welded to the back cover panel, typically made of glass, of a photovoltaic module. According to another embodiment, metal elements 105₁₋ₙ may be based on a composite element formed by build-up of different metal layers. In one exemplary embodiment, metal elements 105₁₋ₙ may include a thin strip of steel ultrasonically welded over an aluminum element, the aluminum element of the composite element allowing for ultrasonic welding to a back cover panel. As such, a composite element may have increased mechanical strength relative to a non-composite metal element. In certain embodiments, polymeric elements may be similarly employed and integrated with the junction box 100 to allow junction box 100 to be ultrasonically-welded to a back cover panel of a photovoltaic module.

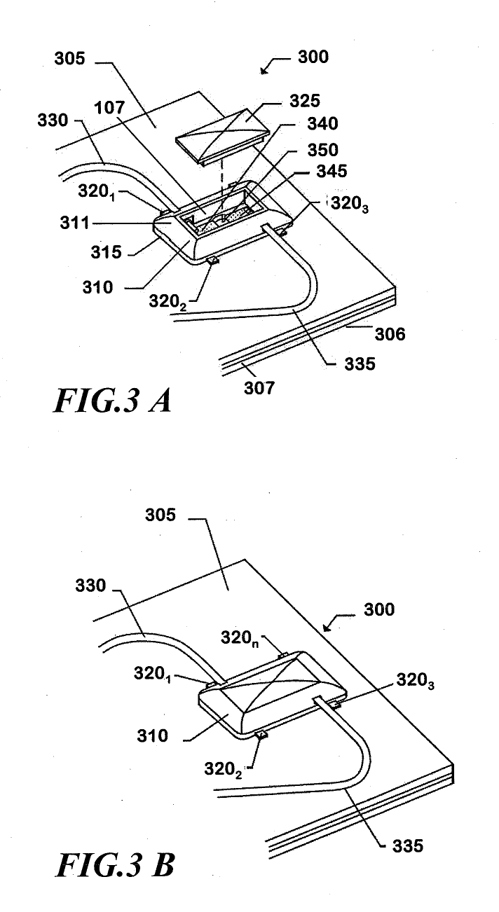

Junction box 100 defines an internal cavity 107 for providing access to internal conductors of a module provided at the opening in the back cover and may additionally include one or more openings 110 to allow for external conductors to be coupled, within cavity 107, to one or more internal conductors of a photovoltaic module. As explained in detail below in connection with FIG. 3A, tape conductors which connect with internal conductors of the photovoltaic module are folded over the edges of the back cover panel opening over which junction box 100 is mounted such that cavity 107 is aligned with the opening, making the tape conductors accessible through cavity 107. The folded over tape can be electrically connected with external module conductors which pass through respective openings 110 and into cavity 107 by, for example, soldering, welding, or a conductive adhesive.

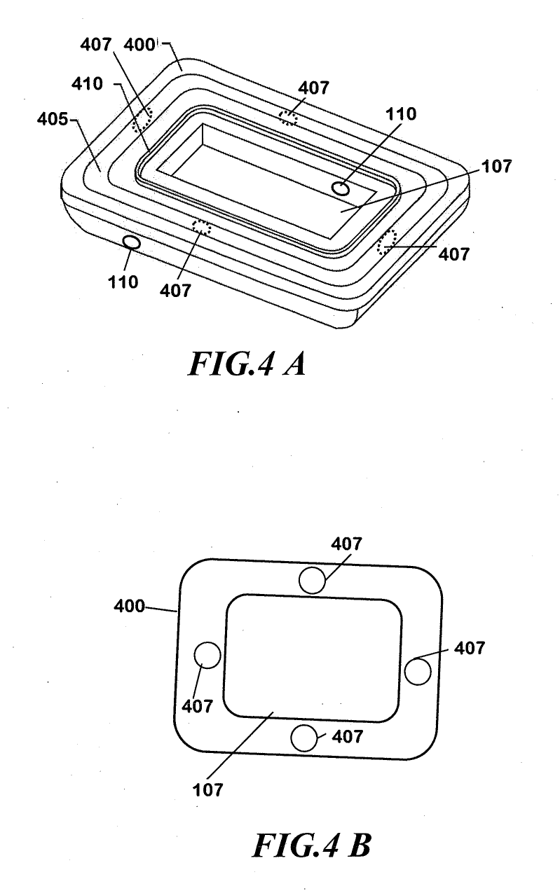

As depicted in FIG. 1B, metal elements 105₁₋ₙ extend outwardly from junction box 100. Metal elements 105₁₋ₙ are formed as tabs or plates, and provide ultrasonic weld points. The welding of junction box 100 to a photovoltaic module may be accompanied by application of a sealant 120 underneath of the junction box prior to welding as will be discussed in more detail below with respect to FIG. 4A, which shows the welding of junction box 100 to a back cover panel of a module.

The thickness of metal elements 105₁₋ₙ may range from 10 micrometers (μm) to 1,000 μM, though a practical thickness range is from 50 micrometers (μm) to 400 μm. At least the surfaces and/or sides of metal elements 105₁₋ₙ in contact with surfaces of junction box 100 may also be corrugated or otherwise roughed to aid in the overmolding and retention of junction box 100 on metal elements 105₁₋ₙ.

Overmolding may be any molding process where two or more materials are combined to produce a single part. In one example, overmolding can seamlessly combine metal elements 105₁₋ₙ with a plastic used to form the body of junction box 100. Overmolding may employ a flowable plastic such as a thermoplastic or a thermoplastic elastomer (TPE). The plastic may also include high temperature amorphous resins or semi-crystalline resins such as acetal, liquid crystal polymer (LCP), polyester, polyamide, polyethylene (PE), polypropylene (PP), poly(phenylene sulfide) PPS, polyetherimide, and polysulfone. TPE is a class of polymers that have the characteristics of thermoset rubber. Unlike rubber, however, TPE can be melted and processed in an injection molding machine. With these qualities, TPE combines the advantages of rubber-like materials with the cost, throughput and quality benefits of injection molding.

According to another embodiment, metal elements 105₁₋ₙ may include one or more features to allow for overmolding a housing to the metal elements or connecting a housing to the elements after metal elements 105₁₋ₙ have been ultrasonically welded to a back cover panel. For example, metal elements 105₁₋ₙ may include features, such as posts, to anchor an overmold of a junction box or allow for a snap fit coupling of a pre-molded junction box housing to the metal element.

Junction box 100 may additionally include, on its underside, sealant layer 120 as shown in FIG. 1B. Sealant layer 120 is provided around the periphery of cavity 107 between the underside of junction box 110 and the back cover panel of a photovoltaic module prior to ultrasonically welding metal elements 105₁₋ₙ to the back cover panel. Sealant layer 120 can include ethylene vinyl acetate, acrylic, polyvinyl butyral, polydimethylsiloxane, polyisobutylene, polyolefin, thermoplastic polyurethane, polyurethane, acrylic foam tape, epoxy, silicone, or ionomer. Although depicted as a dashed line in FIG. 1B, sealant layer 120 may be extend beyond the illustrated portion of 120 or may cover the entire bottom surface of junction box 100.

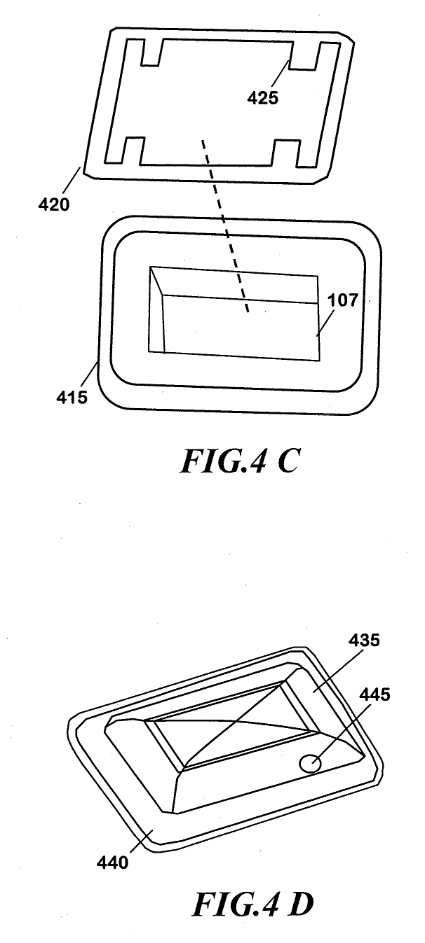

Sealant layer 120 may be one of a liquid sealant, such as a silicone-based sealant, and a tape-based sealant, such as Solar Acrylic Foam Tape manufactured by 3M. Ultrasonic welding of metal elements 105₁₋ₙ of junction box 100 allows for joining junction box 100 to a photovoltaic module to provide instant tacking and ample bonding strength when exposed to high temperatures and high humidity. According to another embodiment, described below in connection with FIGS. 5A-5D, metal elements 105₁₋ₙ of a junction box may allow for buckling under a certain load for providing necessary pressure for a sealing material to cure.

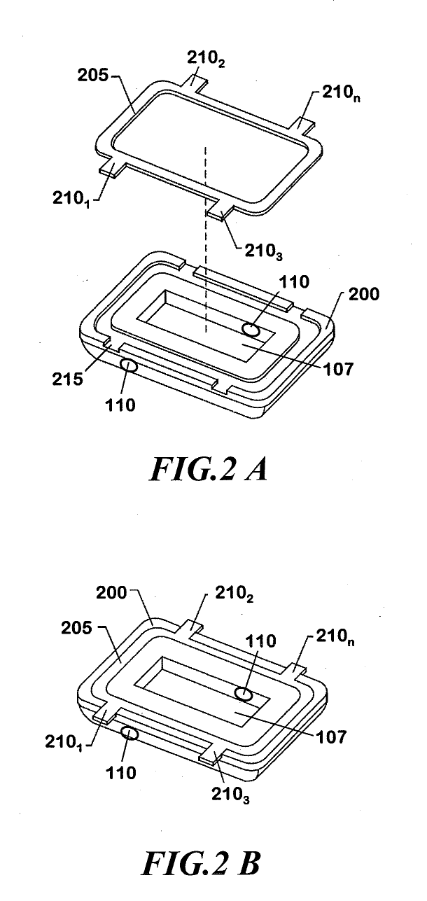

According to another embodiment depicted in FIGS. 2A-2B, metal element 205 may extend around the periphery of the bottom surface of a junction box 200. In FIG. 2A, a bottom disassembled view is depicted of junction box 200 including metal element 205. Metal element 205 is illustrated as a quadrilateral metal bracket including a plurality of tabs 210₁₋ₙ which may extend outwardly beyond junction box 200. An ultrasonic weld can be provided at each of tabs 210₁₋ₙ to a back cover panel of a photovoltaic module around the perimeter of junction box 200. Junction box 200 may be overmolded to metal element 205, as shown in FIG. 2B, and thus, be integrally formed with metal element 205. Metal element 205 may be one of aluminum, copper, nickel, or any other suitable metal. Surfaces of metal element 205 in contact with surfaces of junction box 200 may be corrugated or otherwise roughed to promote adhesion of the two. Coupling of junction box 200 to a back cover panel may include application of a sealant as will be discussed in more detail below with respect to FIG. 4A. The sealant may be applied to a bottom portion of metal element 205 and/or junction box 200. The thickness of metal element 205 may range from 50 μm to 400 μm. It should be appreciated that other thicknesses may be employed as discussed above.

FIGS. 3A-3B depict a photovoltaic module 300 including an attached junction box 310. FIG. 3A depicts photovoltaic module 300 including back cover panel 305, front cover panel 306, a plurality of series connected photovoltaic cells 307 between the front and back cover panels 305 and 306, and junction box 310. Junction box 310 may provide a sealed enclosure for the interconnectors of one or more external wires 330 and 335 to tabs 340 and 345 which connect to internal conductors of photovoltaic module 300. Photovoltaic module 300 may include one or more photovoltaic cells between back cover panel 305 and front cover panel 306.

The photovoltaic module 300 has junction box 310 ultrasonically welded to back cover panel 305. The junction box 310 may employ a plurality of metal elements, such as those employed with junction box 100 depicted in FIGS. 1A-1B. Alternatively, the junction box 310 may have single metal elements with outwardly projecting tabs 210₁₋ₙ. For purposes of illustration, junction box 310 includes metal element 315 having a plurality of tabs shown as 320₁₋ₙ which correspond to tabs 210₁₋ₙ of FIGS. 2A and 2B.

As further depicted in FIG. 3A, junction box 310 may include base portion 311 and a cover portion 325. Cavity 107 of junction box 310, can be enclosed when the cover portion 325 is installed on base portion 311, the cavity 107 defining an area for electrical connections of electrical conductors 330 and 335 to tabs 340 and 355. Such connections are formed after junction box 310 has been ultrasonically welded to back cover panel 305.

As depicted in FIG. 3A, junction box 310 is installed over opening 350 in the back cover panel 305. A first internal conductor 340 and a second internal conductor 345 may extend from opening 350. The first and second internal conductors 340 and 345, which may be tape conductors, may be part of an internal bussing system for photovoltaic cells 307. Once inserted through opening 350 of the substrate, the first internal conductor 340 and second internal conductor 345 are folded back against back cover panel 305 on opposing sides of the opening 350. After the first and second internal conductors 340 and 345 have been folded back against the substrate, junction box 310 is ultrasonically welded to photovoltaic module 300 and external conductors 330, 335 connect to the internal conductors 340, 345.

As noted in the discussion of FIGS. 1A, 1B, 2A and 2B, a sealant may be employed to provide a moisture barrier between base portion 311 of junction box 310 and back cover panel 305. For example, a sealant, such as a liquid or a tape sealant, may be applied to base portion 311 and/or metal element 310 prior to welding. The sealant may additionally act as an adhesive. For example, a silicone-based sealant may be applied to bottom of back portion 311 prior to it being ultrasonically welded to back cover panel 305. The silicone-based sealant may be applied as a bead having a width of about 5 to 25 millimeters (mm) applied to the bottom surface of bottom portion 311. In addition to providing an instant tacking of junction box 310 to back cover panel 305, ultrasonic welding will hold base portion 311 of junction box 310 in a fixed position while the silicone-based sealant cures. Although a silicone-based sealant is described, the sealant may instead include a sealant tape or one of an ethylene vinyl acetate, acrylic, polyvinyl butyral, polydimethylsiloxane, polyisobutylene, polyolefin, thermoplastic polyurethane, acrylic foam tape, polyurethane, epoxy, silicone, ionomer, or a combination thereof.

As depicted, external conductors 330 and 335 can be electrically connected by soldering, welding or conductive adhesive to internal conductors 340 and 345 of photovoltaic module 300 through junction box 310. Wires 330 and 335 may be industry-standard connectors to allow for ease of installation.

Once base portion 311 of junction box 310 has been installed and electrical connections have been made, a potting material can be added to cavity 107. In one example, the potting material may be injected into the junction box and may fill, or nearly fill, the interior of the junction box. The potting material can serve at least three useful functions. First, it may provide an additional moisture barrier that prevents moisture from reaching any inner surfaces of the module that are corrosion-prone. Second, the potting material may serve as an insulating material that prevents short circuiting between the first and second internal conductors 340 and 345 and/or extend conductors 330 and 335. Third, the potting material can provide structural integrity to the components housed within junction box 310. In particular, the potting material may envelop wires 330 and 335 to prevent undesired disconnection from junction box 310. In another embodiment, base portion 311, or junction box 310, may be formed by overmolding to one or more metal elements 310 after electrical connections have been made to back cover panel 305. In this case, the overmolding may fill an entire area between back cover panel 305 and an outer surface of junction box 310.

FIG. 3B depicts photovoltaic module 300, wherein a cover plate 325 of FIG. 3A is coupled to a base portion 311 of junction box 310 to cover and enclose cavity 107.

The photovoltaic (PV) module 300 of FIGS. 3A and 3B may be oriented to receive sunlight through top cover panel 306. When illuminated by sunlight, a plurality of layers of material of internal photovoltaic cells 307 can convert sunlight into electricity using semiconductor technology, which can include any suitable technology, such as copper indium gallium (di)selenide (CIGS) technology, amorphous silicon (a-Si) technology, or cadmium-telluride (CdTe) technology or other.

FIGS. 4A-4C depict junction box configurations according to additional embodiments. As depicted in FIG. 4A, the underside of junction box 400 includes an overmolded metal element 405 which has similar characteristics as the metal element of FIGS. 2A-2B described above. Metal element 405 extends around the perimeter of the bottom surface of junction box 400. As shown in FIG. 4B, junction box 400 has spaced holes 407 in its top surface extending down to metal element 405 which allows an ultrasonic welding tool to enter therein and weld the metal element 405 to a back cover panel of a photovoltaic module. Holes 407 are depicted as dotted lines in FIG. 4A. Seal 410 may be applied to junction box 400 to help ultrasonically welding of junction box 400 to a back cover panel of a module. Seal 410 may be provided as an alternative to, or in addition to, a later applied sealant (e.g., a silicone-based sealant or tape based sealant). Seal 410 may be formed during overmolding of junction box 400 to metal element 405 and extends from the bottom surface of junction box 400. During ultrasonic welding of metal element 405 to a back cover panel, seal 410 compresses against the back cover panel of a module. As a result, seal 410 provides an additional water-tight seal that prevents moisture from accessing the inner surfaces of the photovoltaic module through an opening in the back cover panel. In one example, the seal may be formed from a thermo plastic elastomeric (TPE) to provide suitable compressibility characteristics. Alternatively, any other compatible seal material may be employed.

After junction box 400 is ultrasonically welded in place through holes 407, and connections between external conductors and internal module conductors have been made within cavity 107 in the manner described above with respect to FIGS. 3A and 3B, a cover can close cavity 107 in the manner shown in FIG. 3B.

FIG. 4C depicts junction box 415 according to another embodiment including overmolded metal element 420. Tabs of metal element 420, such as tab 425, may extend into cavity 107 of a junction box 415. As such, tabs 425 of metal element 420 may be ultrasonically welded to a back cover panel through cavity 107. Tabs 425 of metal element 420 may be positioned to avoid the folded over tabs (e.g., tabs 340 and 345 of FIG. 3A) of a photovoltaic module.

FIG. 4D depicts a top view of junction box 435 in another embodiment including an overmolded metal element 440 which has a portion which extends outwardly beyond the entire perimeter of junction box 435. The outwardly extending portion of metal element 440 may be ultrasonically welded around the perimeter of junction box 435 to a back cover panel of a photovoltaic module. Junction box 435 also includes openings 445 that may receive one or more external conductors.

FIGS. 5A-5D depict alternative arrangements of one or more ultrasonically weldable metal elements which extend beyond a junction box. Metal elements 505 are modifications of the metal elements shown in any of FIGS. 1A-1B, or FIGS. 2A-2B. The modifications of the metal elements in FIGS. 1A-1B, or FIGS. 2A-2B, 4C or 4D includes a buckling portion 510a, 510b, 510c, or 510d. Metal element 505 may be overmolded to a junction box as described above in connection with FIGS. 1A, 1B, 2A, 2B, and 4C-4D. Metal element portions 510a, 510b, 510c and 510d in respective FIGS. 5A-5D, are configured to buckle under pressure of an ultrasonic welding tool to force portions 510a-510d to be flattened against the back cover panel 550. FIG. 5A depicts metal element 505 including buckling portion 510a which includes a downward pointing protrusion. When the ultrasonic welding applies pressure to the portion 510a to flatten it out, this pressure is also mechanically applied to junction box 520 forcing it against back cover panel 550. FIG. 5b depicts metal element 505 including buckling portion 510b which includes an upward pointing protrusion. FIG. 5C depicts metal element 505 including buckling portion 510c which includes a curving protrusion that curves out and down. FIG. 5D depicts metal element 505 including buckling portion 510d which includes a curving protrusion that curves out and up. Buckling portions 510a-510d are configured to flatten out when ultrasonic welding applies pressure to the bucking portion, such that the pressure is also mechanically applied to junction box 520 forcing it against back cover panel 550. Accordingly, any liquid or tape sealant 540 between junction box 520 and back cover panel 550 is compressed and then held in that condition by the ultrasonic weld, thereby providing a secure sealing of the junction box 520 to the back cover panel 550 while the sealant 540 completely cures.

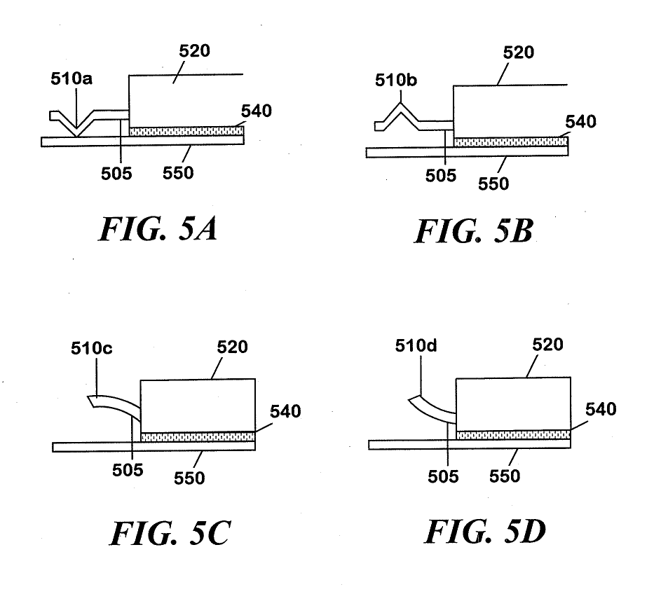

FIG. 6 depicts a method for coupling a junction box to a back cover panel according to one embodiment. Method 600 is initiated by positioning a junction box adjacent to and over a hole in a back cover panel at step 605. The junction box (e.g., junction box of FIGS. 1A-1B, 2A-2B, or 4A-4D) may include at least one metal element for ultrasonically welded to a back cover panel of a module. The junction box may also include one or more of a sealant (e.g., seal 410) and/or a sealant applied to the bottom portion of the junction box as described above in the various embodiments. The junction box is positioned in contact with a back cover panel to allow for ultrasonic welding of the at least one metal element to the back cover panel. A back cover panel may be formed of a glass, such as borosilicate glass, soda lime glass, a metallic glass, foamed of a metal or formed of a polymer, such as a polymeric material. A metallic glass may be an alloy having an amorphous or glassy structure.

At block 610, the at least one metal element may be ultrasonically-welded to the back cover panel. Ultrasonic welding can include any industrial technique where high-frequency ultrasonic acoustic vibrations are applied to create a weld between similar or dissimilar materials. The welding may be performed by an ultrasonic welding machine. Ultrasonic welding works particularly well with thin metals, since they are unable to effectively dissipate all heat generated by the ultrasonic waves and, therefore, melt at the joint area. Upon cooling, the metal solidifies to form a joint and provides a very quick tack time. According to another embodiment, ultrasonic welding may include welding of a polymeric material element, rather than a metal element, to a glass, metal or polymeric back cover panel.

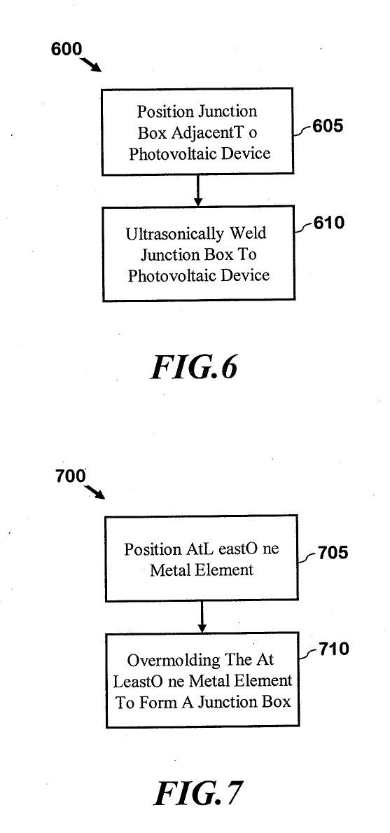

FIG. 7 depicts a method for forming a junction box for a photovoltaic module according to one embodiment. Method 700 may be initiated by positioning at least one metal element at block 705. At block 710, a junction box may be formed by over molding the at least one metal element. The junction box formed at block 710 may be any of the junction boxes described above with reference to FIGS. 1A-1B, 2A-2B, or 4A-4D). In certain embodiments, forming the junction box may include forming one or more holes or openings in the junction box to allow for ultrasonically welding of the at least one metal element through the opening. Similarly, forming the junction box at block 710 may include providing a seal (e.g., seal 410) on the bottom portion of the junction box. The junction box formed by method 900 may be positioned to be in contact with a back cover panel to allow for ultrasonic welding of the at least one metal element of the back cover panel.

While exemplary embodiments have been recited herein, it will be understood by those skilled in the art that various changes in form and details may be made therein without departing from the scope of the invention which is defined solely by the appended claims.

What is claimed is:

1. A photovoltaic module comprising:
a front cover panel;
a back cover panel;
at least one photovoltaic cell formed by a plurality of layers of material between the front and back cover panels; and
a junction box including at least one element, said at least one element being ultrasonically welded to the back cover panel.

2. The photovoltaic module of claim 1, the at least one element comprises at least one metal element.

3. The photovoltaic module of claim 2, wherein the back cover panel is made of glass.

4. The photovoltaic module of claim 2, further comprising a sealing material between the junction box and back cover panel.

5. The photovoltaic module of claim 4, wherein the sealing material comprises at least one of ethylene vinyl acetate, acrylic, polyvinyl butyral, polydimethylsiloxane, polyisobutylene, polyolefin, thermoplastic polyurethane, polyurethane, acrylic foam tape, epoxy, silicone, or ionomer.

6. The photovoltaic module of claim 2, wherein the at least one metal element comprises a plurality of metal tabs.

7. The photovoltaic module of claim 2, wherein the at least one metal element comprises a metal element extending around a perimeter of the junction box.

8. The photovoltaic module of claim 7, wherein the metal element includes a plurality of tabs which extend outwardly beyond the junction box.

9. The photovoltaic module of claim 7, wherein the metal element includes a plurality of tabs which extend inwardly into a cavity defined by the junction box.

10. The photovoltaic module of claim 2, wherein the junction box is overmolded to the at least one metal element.

11. The photovoltaic module of claim 10, the at least one metal element having a curving outer surface in contact with the junction box.

12. The photovoltaic module of claim 2, wherein the at least one metal element is provided on the undersurface of said junction box and said junction box includes one or more openings to allow means for ultrasonic welding to said at least one metal element.

13. The photovoltaic module of claim 2, wherein the at least one metal element of the junction box is configured to buckle and apply a downward pressure on the junction box when the at least one metal element is ultrasonically welded to the back cover panel.

14. The photovoltaic module of claim 2, wherein the at least one metal element includes a pair of tabs on a first side of the junction box and a pair of tabs on a second side of the junction box, wherein only a portion of the tabs are overmolded.

15. The photovoltaic module of claim 2, wherein the at least one metal element is a metal element extending continuously around a perimeter of the junction box, the metal element including tabs extending outwardly beyond the junction box or within the perimeter, and wherein only a portion of the tabs are overmolded.

16. The photovoltaic module of claim 2, wherein the at least one metal element is a metal element extending continuously around a perimeter of the junction box, the metal element including tabs extending individually into a cavity defined by the junction box.

17. The photovoltaic module of claim 1, wherein the at least one element of the junction box comprises a polymeric material.

18. The photovoltaic module of claim 1, wherein the at least one element of the junction box is configured to anchor the junction box to the back cover panel.

19. The photovoltaic module of claim 1, wherein the junction box further comprises a housing overmolded to the at least one element, said housing filling an area between the at least one element and outer surface of the housing.

20. The photovoltaic module of claim 2, wherein the at least one metal element comprises a composite element formed by build-up of different metal layers.

21. A method for coupling a junction box to a back cover panel of a photovoltaic module, the method comprising the acts of:
positioning a junction box adjacent to a back cover panel of a photovoltaic module, the junction box including at least one ultrasonically weldable element; and
ultrasonically welding the at least one element of the junction box to the back cover panel.

22. The method of claim 21, the at least one ultrasonically weldable element comprises at least one metal element.

23. The method of claim 22, further comprising applying a sealing material between the junction box and back cover panel.

24. The method of claim 23, wherein the sealing material comprises at least one of ethylene vinyl acetate, acrylic, polyvinyl butyral, polydimethylsiloxane, polyisobutylene, polyolefin, thermoplastic polyurethane, polyurethane, acrylic foam tape, epoxy, silicone, or ionomer.

25. The method of claim 22, wherein the at least one metal element comprises a plurality of metal tabs.

26. The method of claim 22, wherein the at least one metal element comprises to a metal element extending around a perimeter of the junction box.

27. The method of claim 23, wherein the metal element includes a plurality of tabs which extend outwardly beyond the junction box.

28. The method of claim 26, wherein the metal element includes a plurality of tabs which extend inwardly into a cavity defined by the junction box.

29. The method of claim 22, wherein the junction box is overmolded to the at least one metal element.

30. The method of claim 22, wherein the at least one metal element is configured to buckle and apply a downward pressure on the junction box when the at least one metal element is ultrasonically welded to the back cover panel.
